(19) United States
(12) Patent Application Publication
(10) Pub. No.: US 2026/0313829 A1
(43) Pub. Date: Oct. 8, 2026

(54) FAN MOUNTING STRUCTURE, CONTAINER FOR ARRANGING SPECIAL COMPUTING DEVICE, CONNECTION FRAMEWORK AND SUPPORTING FRAME

(71) Applicant: CANAAN CREATIVE CO., LTD., Beijing (CN)

(72) Inventors: Guanchao Zhao, Beijing (CN); Nan Li, Beijing (CN); Shishuang He, Beijing (CN); Zonghai Chen, Beijing (CN); Xiaogang Sun, Beijing (CN); Xiaoye Zhao, Beijing (CN); He Ying, Beijing (CN); Nangeng Zhang, Beijing (CN)

(21) Appl. No.: 19/479,591

(22) PCT Filed: Mar. 7, 2024
(86) PCT No.: PCT/CN2024/080552

§ 371 Date: Oct. 28, 2025

(30) Foreign Application Priority Data
Apr. 28, 2023 (CN) 202321024279.8
May 17, 2023 (CN) 202321197453.9

(51) Int. Cl. H05K 7/20; G06F 1/20

(52) U.S. Cl. CPC H05K 7/20172; G06F 1/20

(57) ABSTRACT

A fan mounting structure, a container for arranging a special computing device, a connection framework and a supporting frame. The fan mounting structure (2) is mounted on a side surface of the container (1), and comprises a connection framework (21) and a supporting frame (23) for mounting a fan. The fan is mounted inside or outside the container (1) by means of the connection framework (21) and the supporting frame (23), the connection framework (21) is connected to the side surface of the container (1), and the supporting frame (23) is detachably connected to the connection framework (21). It is convenient to transport the container for mounting a computing device during long-term shipping, and the container can be easily mounted with a standard shipping container, has strong standardization and versatility, and is easy to mount and use.

The present application claims priority to China Patent Application No. 202321024279.8 filed on Apr. 28, 2023, and priority to China Patent Application No. 202321197453.9 filed on May 17, 2023, which are incorporated herein by reference for all purposes as if fully set forth herein.

### TECHNICAL FIELD

The present application relates to dedicated container equipment, specifically, to a fan mounting structure, a container for arranging a special computing device, a connection framework and a supporting frame.

### BACKGROUND

Existing dedicated containers used to install computing devices are easily damaged during long sea transport, causing huge economic losses.

When fans are mounted outside the containers, there is more internal heat dissipation space and wider passages for maintenance personnel to work and operate. Therefore, disposing fans outside has many advantages. However, this way of mounting is not convenient for transportation and will take up more storage and transportation space, increasing transportation costs.

Therefore, existing dedicated containers cannot be used in conjunction with standard shipping containers in a very convenient manner, have poor standardization and versatility, and are inconvenient to install, operate, and use.

### SUMMARY

A purpose of the present application is to provide a fan mounting structure, a container for arranging a special computing device, a connection framework and a supporting frame, so as to solve the technical problems that it is inconvenient to transport when fans are disposed outside the container, and the existing dedicated containers cannot be installed in conjunction with standard shipping containers in a very convenient manner, have poor standardization and versatility, and are inconvenient to install and use.

To achieve the aforementioned purpose, the present application provides a fan mounting structure mounted to a side surface of a container, including a connection framework and a supporting frame both configured to mount a fan, wherein the fan is mountable inside or outside the container by means of the connection framework and the supporting frame.

The connection framework is connected to the side surface of the container, and the supporting frame is detachably connected to the connection framework.

The supporting frame is detachably connected to a side of the connection framework facing interior of the container, and the fan is disposed inside the container by means of the supporting frame.

The supporting frame is detachably connected to a side of the connection framework facing exterior of the container, and the fan is disposed outside the container by means of the supporting frame.

The fan is at least partially supported by the connection framework, and another portion of the fan is supported by the supporting frame.

A plane of a support portion of the connection framework supporting the fan is substantially coplanar with a plane of a support portion of the supporting frame supporting the fan.

The connection framework is connected to a top side beam and a bottom side beam of the container.

The connection framework is further partially connected to a front corner post or a rear corner post of the container.

Further, a plurality of groups of connection frameworks are provided along the side surface of the container, wherein at least one group of connection frameworks is partially connected to a rear corner post of the container, and at least one group of connection frameworks is partially connected to a front corner post of the container.

The connection framework is in a structure of a square with a vertical divider and a horizontal divider (that is in the shape of Chinese character [symbol] ); four fans are respectively mounted corresponding to four openings of the structure of a square with a vertical divider and a horizontal divider of the connection framework.

Further, the fan mounting structure further includes a fan sealing cover configured to seal a gap between the fan and the connection framework.

A sealant layer is further provided between the fan sealing cover, a fan housing and/or the connection framework.

The fan sealing cover is fixed on the fan and/or the connection framework by a fastener.

The supporting frame includes a fixing portion configured to be detachably connected to the connection framework by a fastener and a support portion configured to support the fan.

Further, the supporting frame includes a limiting portion configured to limit displacement of the fan.

Further, a metal sheet is bent and processed to form the fixing portion, the support portion and a limiting portion of the supporting frame.

The supporting frame further includes:
a first supporting frame further including a first support fixing portion and a first limiting fixing portion, a first support portion and a first limiting portion, wherein the first support fixing portion is connected to the first support portion, the first limiting fixing portion is bent and connected to the first limiting portion, and the first support fixing portion is processed into the first support portion by means of bending.

Further, the first support fixing portion and the first limiting fixing portion are located in the same plane and are respectively connected to a bottom frame of the connection framework.

Further, the first support portion and the first support fixing portion have a L-shaped strip cross-section;
wherein the first supporting frame further includes an auxiliary support member connected to the first support portion and the first support fixing portion, respectively.

The supporting frame further includes: a second supporting frame,
the second supporting frame includes:
   a second support portion configured to support and limit vertical displacement of the fan;
   a second support fixing portion configured to be fixedly connected to the connection framework; and
   a second support limiting portion configured to limit horizontal displacement of the fan.

Further, the second support portion is fixedly connected to the second support limiting portion, and the second support limiting portion is connected to the second support fixing portion.

The second support limiting portion is a plate in the shape of a trapezoid, and the second support fixing portion is bent and formed at a bottom edge of the second support limiting portion in the shape of a trapezoid;
wherein the second support portion in the shape of a rectangular strip is connected to the middle of the second support limiting portion; the second support portion includes two parts, which are, an upper part and a lower part, configured to respectively support or fix an upper fan or a lower fan. The second support portion further includes reinforcement members vertically disposed at both ends.

The first supporting frame is disposed on a bottom edge frame of the connection framework, and the second supporting frame is disposed in the middle of the connection framework.

In order to better achieve the aforementioned purpose of the present application, the present application further provides a container for arranging a special computing device, wherein the above-described fan mounting structure is detachably mounted to a side surface of the container, whereby it is very convenient to make the adjustment of disposing the fan mounting structure inside or outside according to actual needs. The fan mounting structure is mounted to the side surface of the container. The fan mounting structure includes the connection framework and the supporting frame both configured to mount the fan, wherein the fan is mountable inside or outside the container by means of the connection framework and the supporting frame.

The present application further provides a supporting frame for use in the aforementioned fan mounting structure, wherein the fan mounting structure is mounted to the side surface of the container, including the connection framework and the supporting frame both configured to mount the fan, wherein the fan is mountable inside or outside the container by means of the connection framework and the supporting frame.

The present application also provides a connection framework for use in a fan mounting structure. The fan mounting structure described here is mounted to a side surface of a container, and includes a connection framework and a supporting frame configured to mount the fan. The fan is mountable inside or outside the container by means of the connection framework and the supporting frame.

The beneficial effect of the present application lies in that it is convenient to transport the container for arranging a computing device during long-term shipping, and the container can be mounted in conjunction with a standard shipping container in a very convenient manner, has strong standardization and versatility, and is easy to mount and use.

The present application is described in detail below with reference to the accompanying drawings and specific embodiments, but is not intended to limit the present application.

### BRIEF DESCRIPTION OF THE DRAWINGS

FIG. 1 is a schematic structural diagram of fitting a dedicated container into a standard shipping container according to an implementation of the present application;

FIG. 2 is a schematic structural diagram of fitting a dedicated container into a standard shipping container according to an implementation of the present application;

FIG. 3 is a schematic structural diagram, with a fan mounting structure mounted to the position of a side surface of a container according to another implementation of the present application;

FIG. 4 is a schematic structural diagram, with a fan mounting structure mounted to the position of a side surface of a container according to another implementation of the present application;

FIGS. 5 and 6 are exploded views of the structure shown in FIG. 4;

FIG. 7 is a partial enlarged view of the structure shown in FIG. 6, with fans mounted to the position of a side surface of a container;

FIG. 8 is a schematic structural diagram of a first supporting frame in an implementation of the present application;

FIG. 9 is a schematic structural diagram of a second supporting frame in an implementation of the present application;

FIG. 10 is a schematic structural diagram embodying mounting of a water baffle according to an implementation of the present application;

FIG. 11 is a schematic structural diagram of a connection framework according to an implementation of the present application;

FIG. 12 is a schematic structural diagram of another connection framework according to an implementation of the present application;

FIG. 13 is a schematic structural diagram embodying connection relationship between a sealing frame cover, a sealant layer, a fan and a connection framework according to an implementation of the present application.

### NOTES OF REFERENCE NUMERALS

1—container;
11—front corner post;
12—bottom side beam;
13—top side beam;
2—fan mounting structure;
21—connection framework;
22—fan;
221—fan sealing cover;
222—sealant layer;
23—supporting frame;
231—first supporting frame;
2311—first support fixing portion;
2312—first limiting fixing portion;
2313—first support portion;
2314—first limiting portion;
2315—auxiliary support member;
232—second supporting frame;
2321—second support fixing portion;
2323—second support portion;
23231—second support portion upper member;
23232—second support portion lower member;
23233—first reinforcement member;
23234—second reinforcement member;
2324—second support limiting portion;
25—water baffle.

### DETAILED DESCRIPTION

The technical solution of the present application is described in detail below in conjunction with the accompanying drawings and specific embodiments to further understand the purpose, solution and efficacy of the present application, but it is not intended to limit the scope of protection of the claims of the present application.

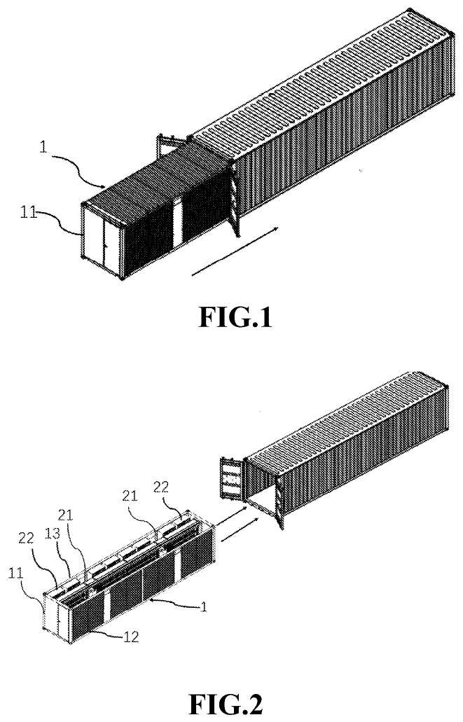

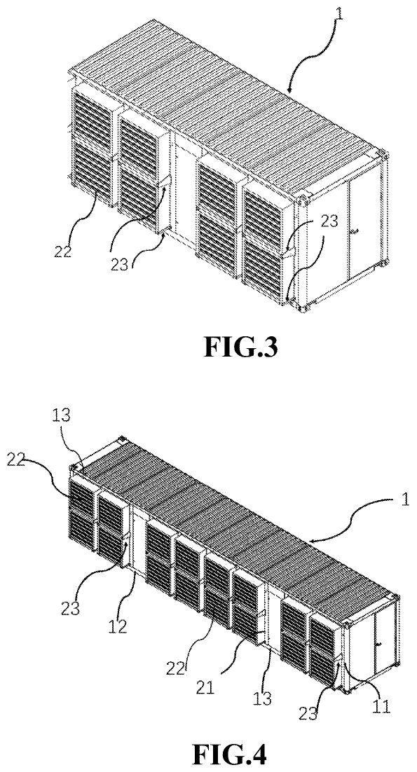

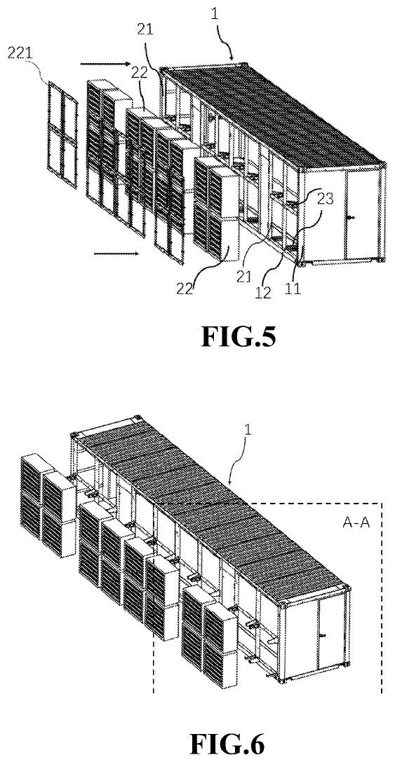

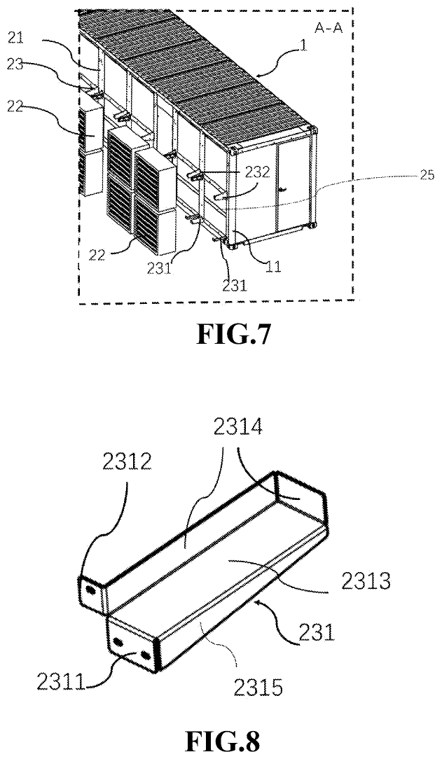

As shown in FIGS. 1-10, an implementation of the present application provides a fan mounting structure 2 mounted on a side surface of a container 1. The fan mounting structure 2 includes a connection framework 21 and a supporting frame 23 both configured to mount a fan. The fan is mountable inside or outside the container by means of the connection framework 21 and the supporting frame 23.

The connecting frame 21 is connected to the side surface of the container 1, and the supporting frame 23 is detachably connected to the connecting frame 21.

The supporting frame 23 is detachably connected to a side of the connection framework 21 facing interior of the container 1, and the fan 22 is disposed inside the container 1 by means of the supporting frame 23. Alternatively, the supporting frame 23 is detachably connected to a side of the connection framework 21 facing exterior of the container 1, and the fan 22 is disposed outside the container 1 by means of the supporting frame 23.

The fan 22 is at least partially supported by the connection framework 21, and another portion of the fan 22 is supported by the supporting frame.

A plane of a support portion of the connection framework 21 supporting the fan 22 is substantially coplanar with a plane of a support portion of the supporting frame 23 supporting the fan 22. In the present embodiment, it is disclosed here as being substantially coplanar in order to facilitate the switching of the fan between disposing inside and outside, ensuring that the plane where the support portion of the connection framework supports the fan and the plane where the support portion of the supporting frame supports the fan can smoothly promote the fan to be switched between disposing inside and outside. It should be noted that being substantially coplanar here means that the two planes are located within the position range that can facilitate the switching of the fan between disposing inside and outside. For instance, substantially coplanar includes two situations. One situation is that the plane where the support portion of the connection framework 21 supports the fan 22 is the same plane as the plane where the support portion of the supporting frame 23 supports the fan 22. The other situation is that the distance between the plane where the support portion of the connection framework 21 supports the fan 22 and the plane where the support portion of the supporting frame 23 supports the fan 22 is less than 15 mm. It should be noted that the above are merely examples and the present application is not limited thereto, only if it can be done as long as it is within the position range that facilitates the switching of the fan between disposing inside and outside.

The connection framework 21 is connected to a top side beam 13 and a bottom side beam 12 of the container 1.

As described above, in the present embodiment, the fan mounting structure is detachably mounted to a side surface of the container, whereby it is very convenient to make the adjustment of disposing the fan mounting structure inside or outside according to actual needs. The fan mounting structure enables the fan to be disposed on the supporting frame and is switchable between positions on an outer surface and an inner surface of the container so as to be movably mounted.

It is worth noting that in the embodiments of the present application, the frame of the container 1 is pre-mounted with mounting holes (for example, blind rivet holes), which facilitates installation without the need for on-site drilling, thereby facilitating the installation of structures such as the fan 22 and the water curtain.

The connection framework 21 is further partially connected to a front corner post 11 or a rear corner post of the container 1. A plurality of groups of connection frameworks 21 are provided along the side surface of the container 1, among which at least one group of connection frameworks 21 is partially connected to a rear corner post of the container 1, and at least one group of connection frameworks 21 is partially connected to a front corner post 11 of the container 1. In the present embodiment, a plurality of groups of connection frameworks are provided to enable the mounting of a plurality of fans.

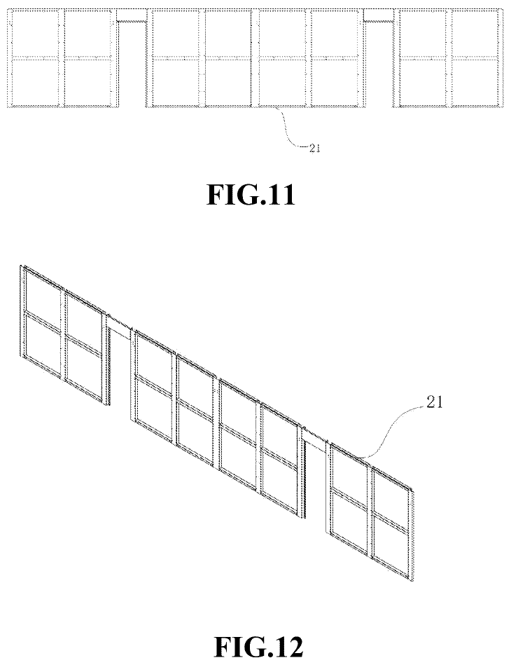

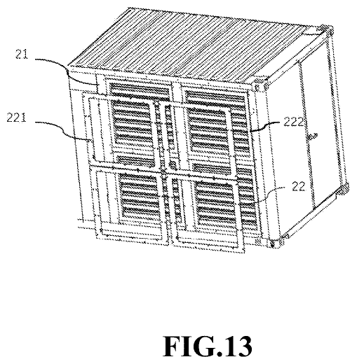

Referring to FIGS. 11-13, it should be noted that the connection framework 21 is a structure like Chinese character “ [symbol] ”, that is a square with a vertical divider and a horizontal divider. Four fans 22 are respectively mounted in this structure of a square with a vertical divider and a horizontal divider corresponding to the connection framework 21. The fan 22 mounting structure 2 further includes a fan 22 sealing cover configured to seal a gap between the fan 22 and the connection framework 21. A sealant layer 222 is further provided between the fan 22 sealing cover, a fan 22 housing and/or the connection framework 21. The fan 22 sealing cover is fixed on the fan 22 and/or the connection framework 21 by a fastener. The fan 22 sealing cover is configured to prevent rainwater from penetrating. The fan 22 sealing cover is fixed on the fan 22 by a plurality of fasteners; alternatively, the fan 22 sealing cover is fixed on the connection framework 21 by passing through the fan 22 housing via a plurality of fasteners. Specifically, the fan 22 sealing cover is provided with two rings of perforations, namely inner and outer rings of perforations. The inner ring of perforations are matched and connected with the fixing holes on the fan 22, and the outer ring of perforations are matched and connected with the fixing holes on the connection framework 21 or the container 1. There is a gap between an outer contour of the fan 22 and the connection framework 21 or the container 1, and a sealing plate seals the gap.

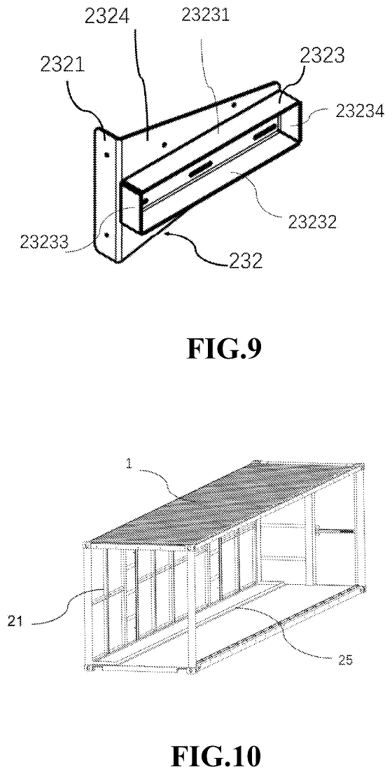

In one or more implementations of the present application, referring to FIGS. 8 and 9, the supporting frame 23 includes a fixing portion and a support portion. The fixing portion is configured to be detachably connected to the connection framework 21 by means of a fastener, and the support portion is configured to support the fan 22. The supporting frame 23 includes a limiting portion configured to limit displacement of the fan 22. A metal sheet is bent and processed to form the fixing portion, the support portion and the limiting portion of the supporting frame 23. By bending and producing a metal sheet into the fixing portion, the support portion and the limiting portion, it makes the supporting frame firmer and has good fixation, which facilitates the connection between the supporting frame and the connection framework and the fan.

As shown in FIGS. 8 and 9, the supporting frame 23 further includes: a first supporting frame 231. The first supporting frame 231 in turn includes a first support fixing portion 2311 and a first limiting fixing portion 2312, as well as a first support portion 2313 and a first limiting portion 2314. The first support fixing portion 2311 is connected to the first support portion 2313, the first limiting fixing portion 2312 is bent and connected to the first limiting portion 2314, and the first support fixing portion 2311 is processed into the first support portion 2313 by bending.

It should be noted that the first support fixing portion 2311 and the first limiting fixing portion 2312 are located in the same plane and are respectively connected to a bottom frame of the connection framework 21. Further, the first support portion 2313 and the first support fixing portion 2311 have an L-shaped strip cross-section, wherein the first support portion 2313 is at the long side and the first support fixing portion 2311 is at the short side. The first supporting frame 231 further includes an auxiliary supporting member 2315. The auxiliary supporting member 2315 is connected to the first support portion 2313 and the first support fixing portion 2311, respectively.

It should be noted that the above description of the specific structure of the first supporting frame 231 is merely an example, and the present application is not limited thereto.

The supporting frame 23 further includes: a second supporting frame 232. In one or more implementations of the present application, the second supporting frame 232 includes: a second support portion 2323 configured to support and limit vertical displacement of the fan 22; a second support fixing portion 2321 configured to be fixedly connected to the connection framework 21; and a second support limiting portion 2324 configured to limit horizontal displacement of the fan 22.

Further, the second support portion 2323 is fixedly connected to the second support limiting portion 2324, and the second support limiting portion 2324 is connected to the second support fixing portion 2321.

The second support limiting portion 2324 is a plate in the shape of a trapezoid, and the second support fixing portion 2321 is bent and formed at a bottom edge of the second support limiting portion 2324 in the shape of a trapezoid.

Further, the second support portion 2323 in the shape of a rectangular strip is connected to the middle of the second support limiting portion 2324. The second support portion 2323 includes two parts, which are, an upper part and a lower part, specifically a second support portion upper member 23231 and a second support portion lower member 23232, configured to respectively support or fix an upper fan and a lower fan. The second support portion 2323 further includes reinforcement members vertically arranged at both ends, respectively a first reinforcement member 23233 and a second reinforcement member 23234.

The first supporting frame 231 is disposed on the bottom frame of the connection framework 21, and the second supporting frame 232 is disposed in the middle of the connection framework 21.

It should be noted that the above description of the specific structure of the second supporting frame 232 is merely an example, and the present application is not limited thereto.

In order to better achieve the aforementioned purpose of the present application, the present application further provides a container 1 for arranging a special computing device, and the above-described fan mounting structure 2 is detachably mounted to a side surface of the container 1, whereby it is very convenient to make the adjustment of disposing the fan 22 mounting structure 2 inside or outside according to actual needs.

To achieve the aforementioned purpose, the present application provides a container 1 for arranging a special computing device. A fan mounting structure 2 is mounted on a side surface of the container 1. The fan mounting structure 2 includes a connection framework 21 and a supporting frame 23 both configured to mount a fan 22. The fan 22 is mountable inside or outside the container 1 by means of the connection framework 21 and the supporting frame 23. The fan mounting structure 2 can adopt the fan mounting structure of the above embodiments as shown in FIGS. 1-13, and its specific structure will not be described in detail in the present embodiment.

It is worth noting that in the present embodiment, a water baffle 25 is further provided on a bottom surface of the container 1 at a side thereof close to the fan 22.

As described above, the container for arranging a special computing device provided in the present embodiment detachably mounts a fan mounting structure to a side surface of the container, whereby it is very convenient to make the adjustment of disposing the fan mounting structure inside or outside according to actual needs. The fan mounting structure enables the fan to be disposed on the supporting frame and is switchable between positions on an outer surface and an inner surface of the container so as to be movably mounted.

Existing dedicated containers configured to dispose computing devices are easily damaged during long-term shipping, causing huge economic losses. Existing dedicated containers cannot be used in conjunction with standard shipping containers in a very convenient manner, have poor standardization and versatility, and are inconvenient to install, operate, and use. The dedicated container for arranging a special computing device provided in the embodiments of the present application solves the technical problems that it is inconvenient to transport when fans are disposed outside the container, and the existing dedicated containers cannot be installed in conjunction with standard shipping containers in a very convenient manner, have poor standardization and versatility, and are inconvenient to install and use.

The present application further provides a supporting frame 23 for use in the aforementioned fan mounting structure 2. The fan mounting structure 2 is mounted to the side surface of the container 1. The fan mounting structure 2 includes the connection framework 21 and the supporting frame 23 both configured to mount the fan 22, wherein the fan 22 is mountable inside or outside the container 1 by means of the connection framework 21 and the supporting frame 23. When using the standard transport container 1 to store and transport the dedicated container, the fan mounting structure 2 is set in the standard transport container body, wherein the total number of supporting frames 23 disposed inside is greater than the number of supporting frames 23 for actual installation by at least one group for use when the fan is changed from being disposed inside to being disposed outside. The fan mounting structure 2 can adopt the fan mounting structure of the above embodiment as shown in FIGS. 1-13, and its specific structure will not be described in detail in the present embodiment.

The present application further provides a connection framework 21 for use in the above-described fan mounting structure 2. The fan 22 mounting structure 2 herein is mounted to the side surface of the container 1. The fan 22 mounting structure 2 includes the connection framework 21 and the supporting frame 23 both configured to mount the fan 22. The fan 22 is mountable inside or outside the container 1 by means of the connection framework 21 and the supporting frame 23. When using the standard transport container 1 to store and transport the dedicated container, the fan mounting structure 2 is set in the standard transport container body, wherein the total number of supporting frames 23 disposed inside is greater than the number of supporting frames 23 for actual installation by at least one group for use when the fan is changed from being disposed inside to being disposed outside. The fan mounting structure 2 can adopt the fan mounting structure of the above embodiments as shown in FIGS. 1-13, and its specific structure will not be described in detail in the present embodiment.

Of course, the present application may have many other embodiments. Without departing from the spirit and essence of the present application, technicians familiar with the field can make various corresponding changes and modifications based on the present application, all of which, however, fall within the scope of protection of the claims of the present application.

### INDUSTRIAL APPLICABILITY

In summary, in any embodiment, the fan mounting structure is mounted to the side surface of the container, and the fan is mountable inside or outside the container by means of the connection framework and the supporting frame. The connection framework is connected to the side surface of the container, and the supporting frame is detachably connected to the connection framework. It is convenient to transport the container for arranging a computing device during long-term shipping, and the container can be mounted in conjunction with a standard shipping container in a very convenient manner by means of the fan mounting structure, has strong standardization and versatility, and is easy to mount and use.

1. A fan mounting structure, mounted to a side surface of a container, comprising a connection framework and a supporting frame both configured to mount a fan, wherein the fan is mountable inside or outside the container by means of the connection framework and the supporting frame.

2. The fan mounting structure as claimed in claim 1, wherein the connection framework is connected to the side surface of the container, and the supporting frame is detachably connected to the connection framework.

3. The fan mounting structure as claimed in claim 2, wherein the supporting frame is detachably connected to a side of the connection framework facing interior of the container, and the fan is disposed inside the container by means of the supporting frame.

4. The fan mounting structure as claimed in claim 2, wherein the supporting frame is detachably connected to a side of the connection framework facing exterior of the container, and the fan is disposed outside the container by means of the supporting frame.

5. The fan mounting structure as claimed in claim 1, wherein the fan is at least partially supported by the connection framework, and another portion of the fan is supported by the supporting frame.

6. The fan mounting structure as claimed in claim 1, wherein a plane of a support portion of the connection framework supporting the fan is substantially coplanar with a plane of a support portion of the supporting frame supporting the fan.

7. The fan mounting structure as claimed in claim 1, wherein the connection framework is connected to a top side beam and a bottom side beam of the container;
wherein the connection framework is further partially connected to a front corner post or a rear corner post of the container.

8. (canceled)

9. The fan mounting structure as claimed in claim 2, wherein connection frameworks are provided in a plurality of groups along the side surface of the container, wherein at least one group of connection frameworks is partially connected to a rear corner post of the container, and at least one group of connection frameworks is partially connected to a front corner post of the container.

10. The fan mounting structure as claimed in claim 1, wherein the connection framework is in a structure of a square with a vertical divider and a horizontal divider, four fans are respectively mounted corresponding to four openings of the structure of a square with a vertical divider and a horizontal divider of the connection framework.

11. The fan mounting structure as claimed in claim 1, further comprising a fan sealing cover configured to seal a gap between the fan and the connection framework;
wherein a sealant layer is further provided between the fan sealing cover, a fan housing and/or the connection framework;
wherein the fan sealing cover is fixed on the fan and/or the connection framework by a fastener.

12-13. (canceled)

14. The fan mounting structure as claimed in claim 1, wherein the supporting frame comprises a fixing portion configured to be detachably connected to the connection framework by a fastener, a support portion configured to support the fan, and a limiting portion configured to limit displacement of the fan;
wherein a metal sheet is bent and processed to form the fixing portion, the support portion and a limiting portion of the supporting frame.

15-16. (canceled)

17. The fan mounting structure as claimed in claim 14, wherein the supporting frame further comprises:
a first supporting frame further comprising a first support fixing portion and a first limiting fixing portion, a first support portion, and a first limiting portion, wherein the first support fixing portion is connected to the first support portion, the first limiting fixing portion is bent and connected to the first limiting portion, and the first support fixing portion is processed into the first support portion by means of bending;
wherein the first support fixing portion and the first limiting fixing portion are located in the same plane and are respectively connected to a bottom frame of the connection framework.

18. (canceled)

19. The fan mounting structure as claimed in claim 17, wherein the first support portion and the first support fixing portion have a L-shaped strip cross-section;
wherein the first supporting frame further comprises an auxiliary support member connected to the first support portion and the first support fixing portion, respectively.

20. (canceled)

21. The fan mounting structure as claimed in claim 14, wherein the supporting frame further comprises: a second supporting frame,
the second supporting frame comprises:
a second support portion configured to support and limit vertical displacement of the fan;
a second support fixing portion configured to be fixedly connected to the connection framework; and
a second support limiting portion configured to limit horizontal displacement of the fan;
wherein the second support portion is fixedly connected to the second support limiting portion, and the second support limiting portion is connected to the second support fixing portion.

22. (canceled)

23. The fan mounting structure as claimed in claim 21, wherein the second support limiting portion is a plate in the shape of a trapezoid, and the second support fixing portion is bent and formed at a bottom edge of the second support limiting portion in the shape of a trapezoid;
wherein the second support portion in the shape of a rectangular strip is connected to the middle of the second support limiting portion;
wherein the second support portion comprises two parts, which are, an upper part and a lower part, configured to respectively support or fix an upper fan and a lower fan;
wherein the second support portion further comprises reinforcement members vertically disposed at both ends.

24-26. (canceled)

27. The fan mounting structure as claimed in claim 23, wherein the first supporting frame is disposed on a bottom edge frame of the connection framework, and the second supporting frame is disposed in the middle of the connection framework.

28. A container for arranging a special computing device, wherein the fan mounting structure as claimed in claim 1 is disposed at one side of the container.

29. The container for arranging the special computing device as claimed in claim 28, wherein a water baffle is further provided on a bottom surface of the container at a side thereof close to the fan.

30. A connection framework for use in the fan mounting structure as claimed in claim 1.

31. A supporting frame for use in the fan mounting structure as claimed in claim 1.
